(19) United States
(12) Patent Application Publication
(10) Pub. No.: US 2010/0308323 A1
(43) Pub. Date: Dec. 9, 2010

(54) Method for improving light extraction efficiency of group-III nitride-based light emitting device

(75) Inventors: Ching-hwa CHANG JEAN, Taoyuan (TW); Jangho CHEN, Taoyuan (TW)

Correspondence Address: BACON & THOMAS, PLLC, 625 SLATERS LANE, FOURTH FLOOR, ALEXANDRIA, VA, 22314-1176, US

(73) Assignee: WALSIN LIHWA CORPORATION, Taoyuan (TW)

(21) Appl. No.: 12/457,303

(22) Filed: Jun. 8, 2009

(51) Int. Cl. H01L 33/00; H01L 21/20

(52) U.S. Cl. 257/43; 438/46; 977/950; 257/103; 438/669; 257/E33.023; 257/E21.09

(57) ABSTRACT

A method for improving light extraction efficiency of a group-III nitride-based light emitting device is disclosed. The method includes the steps of: providing a group-III nitride-based light emitting device having a top surface; disposing a seed layer on the top surface for increasing adhesion of the group-III nitride-based light emitting device; and forming a patterned oxide layer, having a plurality of nanostructure particles, without absorption of visible light on the seed layer. The size and shape of the nanostructure particles are controlled by reaction concentration, time and temperature during the patterned oxide layer formation, thereby improving light extraction efficiency of the group-III nitride-based light emitting device without damaging the group-III nitride-based light emitting device.

### FIELD OF THE INVENTION

The present invention relates to a method for improving light extraction efficiency of a light emitting device, and more particularly, to a group-III nitride-based light emitting device, such as a GaN light emitting device.

### BACKGROUND OF THE INVENTION

Light emitting devices, for example light emitting diodes (LEDs), generate light using one or more materials having refractive indices (typically n˜2.5) much higher than that of air (n=1.0). Typically, light is generated in a multi-layer stack which has at least one exterior surface. The luminous stack surface is intended to release light generated within the multi-layer stack. This luminous stack surface may be in contact with, for example, an encapsulant material. Such encapsulant materials typically have refractive indices in the range of n=1.4 to 1.8. The drop in refractive index encountered by light impinging upon the interface between the luminous stack surface and the encapsulant layer is, therefore, substantial, with the result that much of the light generated within the multi-layer stack is reflected back into the multi-layer stack by that interface. That is, instead of exiting the multi-layer stack with concomitant entry into the encapsulant layer, a large fraction of the light is channeled back into the interior of multi-layer stack where a similar large fraction is absorbed, thereby drastically reducing the external quantum yield of light useful for illumination.

U.S. Pat. No. 6,831,302 discloses patterning of an exterior surface of an n-doped GaN layer which is an exterior layer of the multi-layer stack. Portions of that n-doped layer are removed to create openings which are then covered over, but not filled, with encapsulant material, creating a smooth layer of encapsulant surface against the openings to the depressions in the surface of the n-doped GaN layer. This patterning within the outermost semiconductor layer creates a plurality of disruptive high and low refractive index regions normal to the encapsulant surface. These disruptive regions interrupt the low angle reflection of light at the interface as well as the tendency of light reflected at low angle to be guided back and forth, parallel to and near the luminous stack surface, within the n-doped semiconductor layer, until that trapped light is absorbed without ever exiting the multi-layer stack.

While the formation of depressions in the exterior surface of the multi-layer stack may improve quantum yield for semiconductor based light emitting devices, the patterning process can be time consuming, requiring, for example, etching of epitaxial surfaces which typically requires expensive equipment. The patterning process may also change the electric and chemical characteristics of the light emitting layer which in turn may decrease light emitting efficiency.

Another method for improving the quality of a light emitting device is disclosed by Fujii et al. in U.S. Pub. No. 2007-0121690. Fujii et al. discloses a gallium nitride (GaN) based light emitting diode (LED), wherein light is extracted through a nitrogen face (N-face) of the LED and a surface of the N-face is roughened into one or more hexagonal shaped cones. The roughened surface reduces light reflections occurring repeatedly inside the LED, and thus extracts more light out of the LED. The surface of the N-face is roughened by an anisotropic etching which may comprise a dry etching or a photo-enhanced chemical (PEC) etching.

Although the roughened surface may reduce light reflections occurring repeatedly inside the LED, the etching process may also damage the electric and chemical characteristics of the light emitting device.

Therefore, a method for improving light extraction efficiency of a light emitting device without causing damage to the electric and chemical characteristics is desperately desired.

### SUMMARY OF THE INVENTION

Accordingly, the prior arts are limited by the above problems. It is an object of the present invention to provide a method for improving light extraction efficiency of a group-III nitride-based light emitting device.

In accordance with an aspect of the present invention, a method for improving light extraction efficiency of a group-III nitride-based light emitting device includes the steps of: providing a group-III nitride-based light emitting device having a top surface; disposing a seed layer on the top surface for increasing adhesion of the group-III nitride-based light emitting device; and forming a patterned oxide layer, having a plurality of nanostructure particles, without absorption of visible light on the seed layer. The size and shape of the nanostructure particles are controlled by reaction concentration, time and temperature during the patterned oxide layer formation, thereby improving light extraction efficiency of the group-III nitride-based light emitting device without damaging the group-III nitride-based light emitting device.

Preferably, the seed layer comprises zinc oxide (ZnO), gold (Au), silver (Ag), Tin (Sn), or cobalt (Co).

Preferably, the patterned oxide layer comprises zinc oxide (ZnO), silicon dioxide (SiO₂), titanium dioxide (TiO₂), or aluminum oxide (Al₂O₃).

Preferably, the patterned oxide layer is formed by hydrothermal treatment, thermal evaporation, chemical vapor deposition, or molecular beam epitaxy.

Preferably, the seed layer is disposed by spin coating, dip coating, evaporation, sputtering, atomic layer deposition, electrochemical deposition, pulse laser deposition, metal-organic chemical vapor deposition, or thermal annealing.

Preferably, the nanostructure particles each has a length ranging from 10 nm˜50 μm.

Preferably, the nanostructure particles each has a cross-sectional diameter ranging from 30 nm˜10 μm.

Preferably, the nanostructure particles each has a distance between each other ranging from 10 nm˜1000 μm.

Preferably, the nanostructure particles each has an effective refractive index ranging from 1.5˜2.5.

In accordance with another aspect of the present invention, a group-III nitride-based light emitting device with improved light extraction efficiency includes a group-III nitride-based light emitting device having a top surface; a seed layer on the top surface for increasing adhesion of the group-III nitride-based light emitting device; and a patterned oxide layer, having a plurality of nanostructure particles, without absorption of visible light on the seed layer.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a flow chart of a preferred embodiment according to the present invention;

FIG. 2 is a scanning electron microscope (SEM) image showing a surface attached with nanostructure oxide particles according to the present invention;

FIG. 3 is a scanning electron microscope (SEM) image showing a surface attached with nanostructure oxide particles according to the present invention;

FIG. 4 is a SEM image showing a surface attached with nanostructure zinc oxide particles formed by hydrothermal treatment according to an embodiment of the present invention;

FIG. 5 is a schematic diagram of a nanostructure zinc oxide particle in FIG. 4;

FIG. 6 is a diagram showing variation of refractive index vs. wavelength of the nanostructure zinc oxide particles in FIG. 4;

FIG. 7 is a diagram showing relationship of light output intensity vs. growth time of a 50 mM solution with (solid line) and without (dotted line) nanostructure zinc oxide particles; and

FIG. 8 is a diagram showing relationship of light output intensity vs. growth time of GaN light emitting diode with (solid line) and without (dotted line) nanostructure zinc oxide particles.

### DETAILED DESCRIPTION OF THE PREFERRED EMBODIMENT

The present invention will now be described more specifically with reference to the following embodiment. It is to be noted that the following descriptions of preferred embodiment of this invention are presented herein for purpose of illustration and description only; it is not intended to be exhaustive or to be limited to the precise form disclosed.

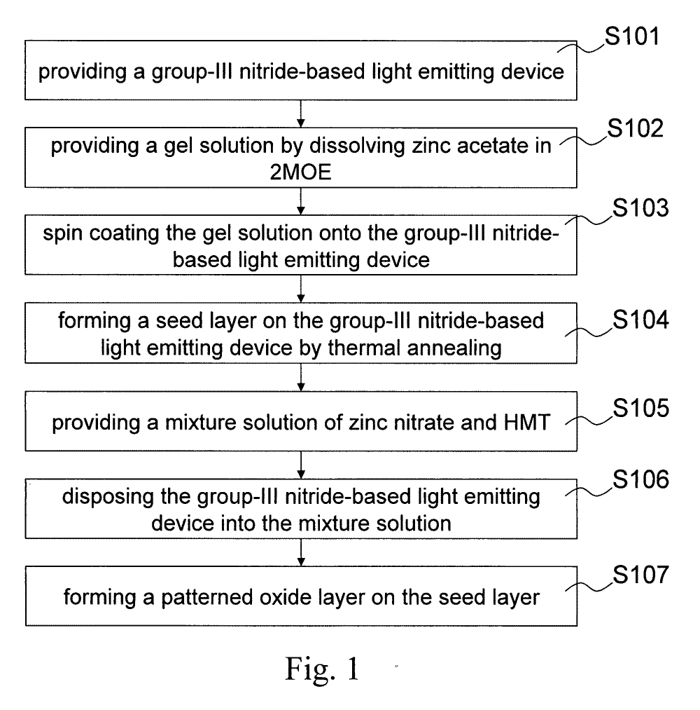

Please refer to FIG. 1. FIG. 1 is a flow chart of a preferred embodiment according to the present invention showing a method for improving light extraction efficiency of a group-III nitride-based light emitting device. In this embodiment, a GaN light emitting diode is used (as shown at step S101). The method of the present invention for improving light extraction efficiency of a group-III nitride-based light emitting device mainly includes the following two steps. First, a seed layer is disposed on a top surface of the GaN light emitting diode for increasing adhesion. Then, a patterned oxide layer having a plurality of nanostructure particles is formed on the seed layer without absorption of visible light. The size and shape of the nanostructure particles can be controlled by reaction concentration, time and temperature during the patterned oxide layer formation. It is found that the size and shape of the nanostructure particles affect the light extraction efficiency of the GaN light emitting diode, and therefore, it is a main object of the present invention to provide a patterned oxide layer over the GaN light emitting diode without changing electric and chemical characteristics thereof.

In order to achieve such an object, for example, a seed layer of zinc oxide (ZnO) is prepared by dissolving zinc acetate (Zn(CH₃COO)₂.H₂O) in 2MOE (CH₃O(CH₂)₂OH, 2-methoxyethanol), each having a concentration of 0.5M, and then stirring the solution for 2 hours while heating at a temperature of 65° C., so that a transparent gel solution is obtained (as shown at step S102). Later, the transparent gel solution is spin coated onto the top surface of the GaN light emitting diode (as shown at step S103). Next, a zinc oxide seed layer is obtained by thermal annealing the GaN light emitting diode having the transparent gel solution deposited thereon at a temperature of 130° C. for 60 minutes (as shown at step S104). In this embodiment, the zinc oxide seed layer is used for zinc oxide nanostructure particles to grow on which in turn a patterned zinc oxide layer is formed.

It should be understood that the seed layer is not limited to be zinc oxide, and can also be gold (Au), silver (Ag), Tin (Sn), or cobalt (Co). Similarly, the patterned oxide layer is not limited to be zinc oxide, and can also be silicon dioxide (SiO₂), titanium dioxide (TiO₂), or aluminum oxide (Al₂O₃).

After the seed layer is formed, prepare a mixture solution of zinc nitrate (Zn(NO₃)₂.6H₂O) and HMT (C₆H₁₂N₄, hexamethylenetetramine), and stir the mixture solution until it completely dissolves (as shown at step S105). Later, dispose the GaN light emitting diode with the seed layer thereon into the mixture solution, and heat it at a low temperature of 90° C. for 2˜4 hours (as shown at step S106). After reaction is completed, take out the GaN light emitting diode and wash it with de-ionized water. Then, dry the GaN light emitting diode, and a patterned oxide layer could be obtained (as shown at step S107).

The aforementioned process for patterned oxide layer formation is the so-called “hydrothermal treatment”. During the hydrothermal treatment, zinc oxide is formed according to the following formulas:

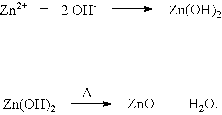

In the aforementioned deposition mechanism, zinc oxide begins to form onto the seed layer once the concentration of zinc ions and hydroxide ions reaches saturation. Due to anisotropic characteristic of atomic bonding, atoms tend to flow towards low energy during nucleation causing asymmetric growth in a specific direction which thereby forms a rod/thread shape array structure.

Although hydrothermal treatment is used in the present embodiment, it should be understood that the present invention is not limited to hydrothermal treatment, and can also use thermal evaporation, chemical vapor deposition, or molecular beam epitaxy.

Moreover, even though spin coating is used for disposing the seed layer onto the GaN light emitting diode in the present embodiment, it should not be limited thereto, and can also use dip coating, evaporation, sputtering, atomic layer deposition, electrochemical deposition, pulse laser deposition, metal-organic chemical vapor deposition, or thermal annealing.

As mentioned above, the size and shape of the nanostructure particles affect the light extraction efficiency of the GaN light emitting diode, and therefore, it is found that a nanostructure particle having a length ranging from 10 nm˜50 μm and a cross-sectional diameter ranging from 30 nm˜10 μm can provide a preferred improvement on light extraction efficiency of the GaN light emitting diode.

Furthermore, the distance between adjacent nanostructure particles is preferred to range from 10 nm˜1000 μm. As aforementioned, the size and shape of the nanostructure particles can be controlled by reaction concentration, time and temperature during the patterned oxide layer formation, and therefore, the effective refractive index of the nanostructure particle may differ according to its size which depends on the reaction concentration, time and temperature during formation. In other words, effective refractive index can be adjusted by controlling the size and shape of the nanostructure particles. Furthermore, light extraction efficiency of the GaN light emitting diode can be improved by adjusting the effective refractive index of the oxide layer according to different wavelengths of light. According to the preferred settings of the present invention, the effective refractive index may ranging from 1.5˜2.5.

Due to the fact that the patterned oxide layer formation can be performed under atmospheric pressure at a temperature approximately 100° C. by hydrothermal treatment, expensive processing equipment and strict operation conditions such as high pressure or high vacuum are not needed. The original structure of the GaN light emitting diode can remain without change neither electrically nor chemically since etching is not introduced. As mentioned above, the shape and size of the nanostructure particles can be controlled, and therefore, light extraction efficiency of the GaN light emitting diode can be improved by adjusting the effective refractive index of the oxide layer according to different wavelengths of light. By the present invention, a larger area and higher density of nanostructure particle array can be obtained due to the low temperature processing condition.

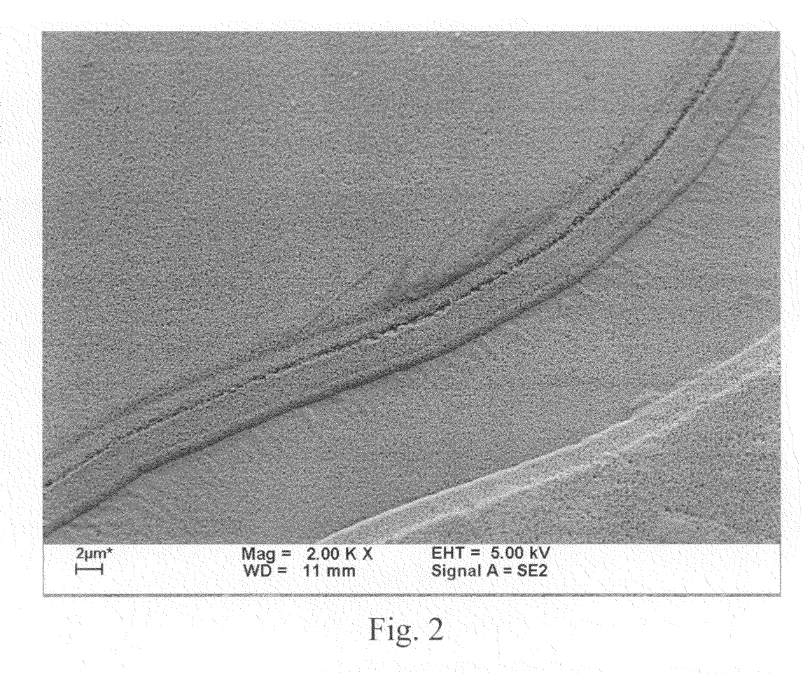

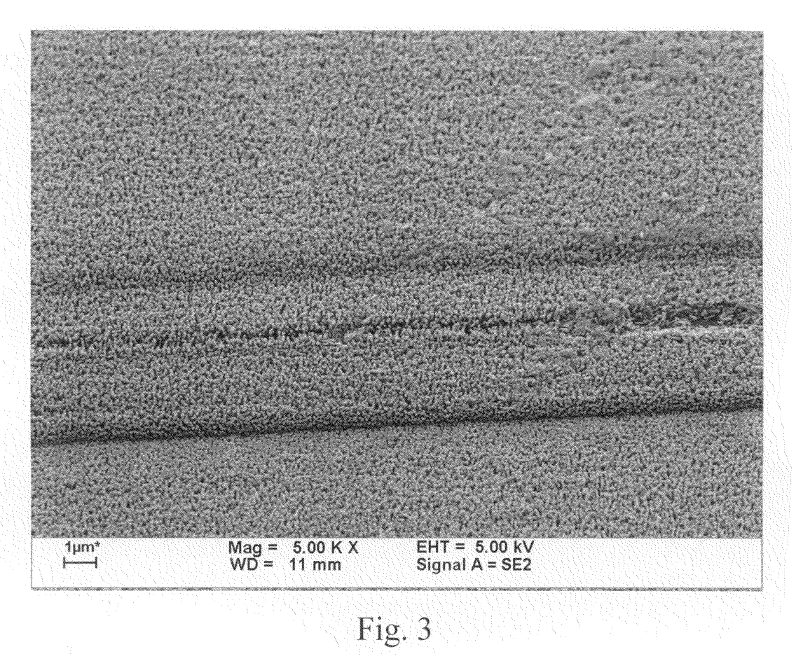

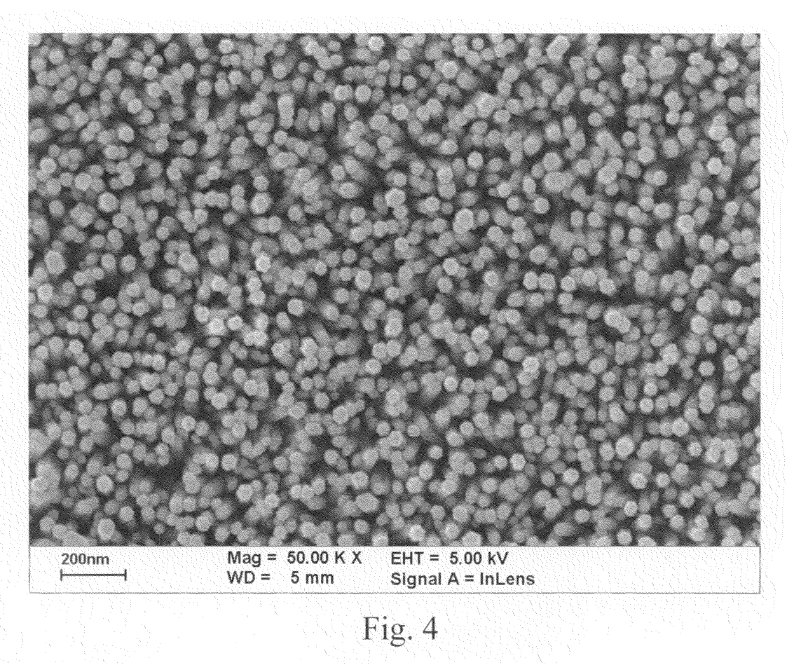

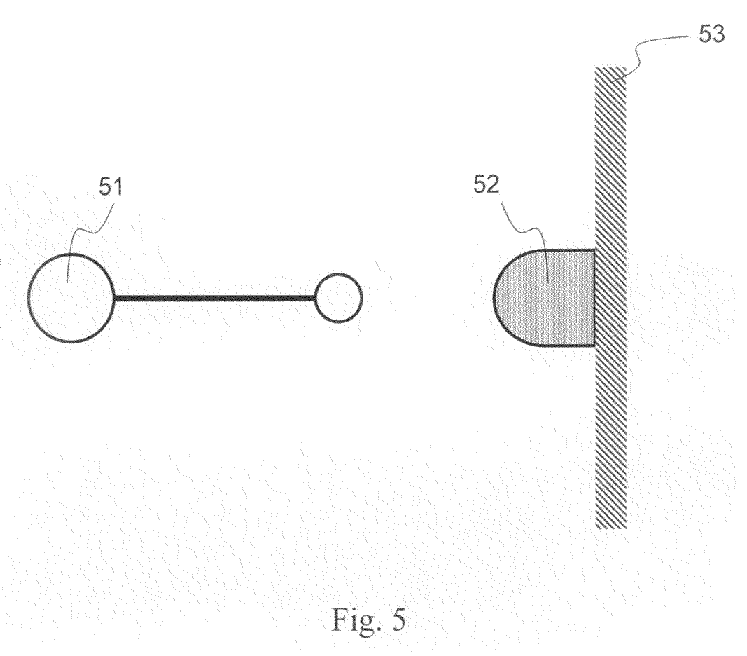

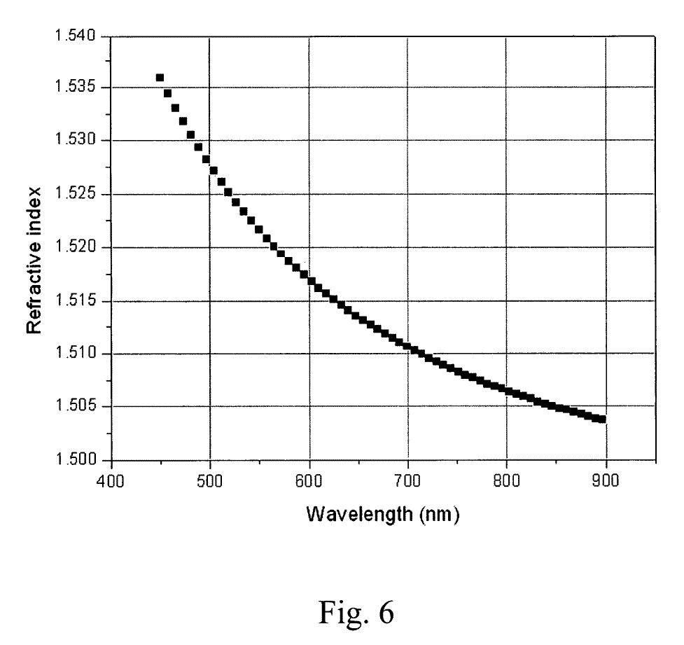

Please refer to FIGS. 2-6. FIGS. 2-3 are scanning electron microscope (SEM) images showing a surface attached with nanostructure oxide particles according to the present invention. FIG. 4 is a SEM image showing a surface attached with nanostructure zinc oxide particles formed by hydrothermal treatment according to an embodiment of the present invention. FIG. 5 is a schematic diagram of a nanostructure zinc oxide particle in FIG. 4 showing a nanostructure zinc oxide particle 51 above a seed layer 52 of a top surface of GaN LED 53. FIG. 6 is a diagram showing variation of refractive index vs. wavelength of the nanostructure zinc oxide particles in FIG. 4. FIGS. 4-6 are under the following conditions:

| | |
|---|---|
| concentration of solution | 50 mM |
| growth time | 3 hours |

The nanostructure particles are formed with a diameter of approximately 50 nm. As shown in FIG. 6, the refractive index of the nanostructure zinc oxide particles is relatively low with respect to that of zinc oxide itself (approximately 2) without nanostructure. The effective refractive index may vary according to the size of the nanostructure zinc oxide particles which differs depending on the concentration of solution during formation.

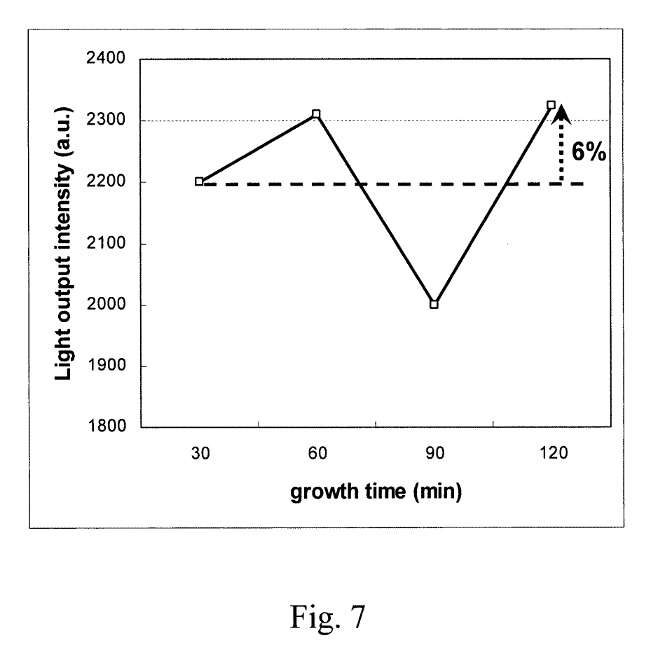

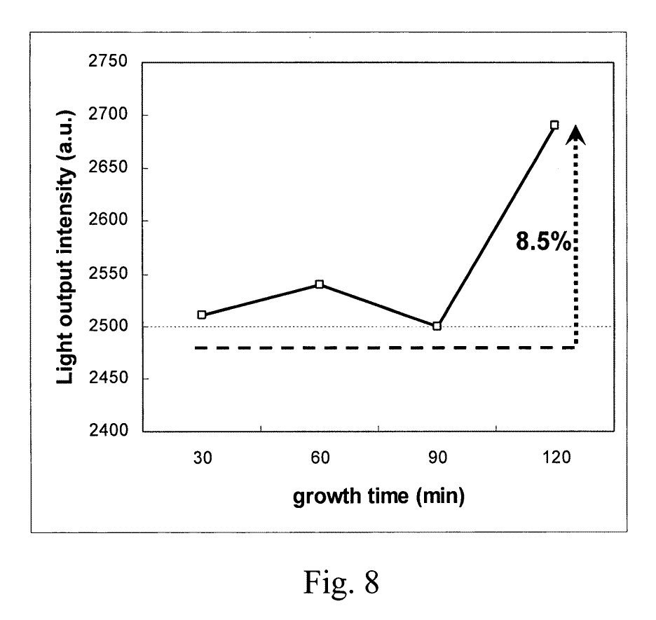

Please refer to FIGS. 7-8. FIG. 7 is a diagram showing relationship of light output intensity vs. growth time of a 50 mM solution with (solid line) and without (dotted line) nanostructure zinc oxide particles. FIG. 8 is a diagram showing relationship of light output intensity vs. growth time of GaN light emitting diode with (solid line) and without (dotted line) nanostructure zinc oxide particles. As shown in FIG. 7, the light output intensity of the 50 mM solution with nanostructure zinc oxide particles at 120 minutes is approximately 6% higher than that without nanostructure zinc oxide particles. Moreover, as shown in FIG. 8, the light output intensity of the GaN light emitting diode with nanostructure zinc oxide particles at 120 minutes is approximately 8.5% higher than that without nanostructure zinc oxide particles. Therefore, it is obvious that the nanostructure zinc oxide particles may significantly improve the light output intensity of the GaN light emitting diode.

While the invention has been described in terms of what is presently considered to be the most practical and preferred embodiment, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A method for improving light extraction efficiency of a group-III nitride-based light emitting device, comprising the steps of:
providing a group-III nitride-based light emitting device having a top surface;
disposing a seed layer on the top surface for increasing adhesion of the group-III nitride-based light emitting device; and
forming a patterned oxide layer, having a plurality of nanostructure particles, without absorption of visible light on the seed layer;
wherein the size and shape of the nanostructure particles are controlled by reaction concentration, time and temperature during the patterned oxide layer formation, thereby improving light extraction efficiency of the group-III nitride-based light emitting device without damaging the group-III nitride-based light emitting device.

2. The method according to claim 1, wherein the seed layer comprises zinc oxide (ZnO), gold (Au), silver (Ag), Tin (Sn), or cobalt (Co).

3. The method according to claim 1, wherein the patterned oxide layer comprises zinc oxide (ZnO), silicon dioxide (SiO₂), titanium dioxide (TiO₂), or aluminum oxide (Al₂O₃).

4. The method according to claim 1, wherein the patterned oxide layer is formed by hydrothermal treatment, thermal evaporation, chemical vapor deposition, or molecular beam epitaxy.

5. The method according to claim 1, wherein the seed layer is disposed by spin coating, dip coating, evaporation, sputtering, atomic layer deposition, electrochemical deposition, pulse laser deposition, metal-organic chemical vapor deposition, or thermal annealing.

6. The method according to claim 1, wherein the nanostructure particles each has a length ranging from 10 nm˜50 μm.

7. The method according to claim 1, wherein the nanostructure particles each has a cross-sectional diameter ranging from 30 nm˜10 μm.

8. The method according to claim 1, wherein the nanostructure particles each has a distance between each other ranging from 10 nm˜1000 μm.

9. The method according to claim 1, wherein the nanostructure particles each has an effective refractive index ranging from 1.5˜2.5.

10. A group-III nitride-based light emitting device with improved light extraction efficiency, comprising:
a group-III nitride-based light emitting device having a top surface;
a seed layer on the top surface for increasing adhesion of the group-III nitride-based light emitting device; and
a patterned oxide layer, having a plurality of nanostructure particles, without absorption of visible light on the seed layer.

11. The group-III nitride-based light emitting device according to claim 10, wherein the seed layer comprises zinc oxide (ZnO), gold (Au), silver (Ag), Tin (Sn), or cobalt (Co).

12. The group-III nitride-based light emitting device according to claim 10, wherein the patterned oxide layer comprises zinc oxide (ZnO), silicon dioxide (SiO₂), titanium dioxide (TiO₂), or aluminum oxide (Al₂O₃).

13. The group-III nitride-based light emitting device according to claim 10, wherein the patterned oxide layer is formed by hydrothermal treatment, thermal evaporation, chemical vapor deposition, or molecular beam epitaxy.

14. The group-III nitride-based light emitting device according to claim 10, wherein the seed layer is formed by spin coating, dip coating, evaporation, sputtering, atomic layer deposition, electrochemical deposition, pulse laser deposition, metal-organic chemical vapor deposition, or thermal annealing.

15. The group-III nitride-based light emitting device according to claim 10, wherein the nanostructure particles each has a length ranging from 10 nm˜50 μm.

16. The group-III nitride-based light emitting device according to claim 10, wherein the nanostructure particles each has a cross-sectional diameter ranging from 30 nm˜10 μm.

17. The group-III nitride-based light emitting device according to claim 10, wherein the nanostructure particles each has a distance between each other ranging from 10 nm˜10 μm.

18. The group-III nitride-based light emitting device according to claim 10, wherein the nanostructure particles each has an effective refractive index ranging from 1.5˜2.5.
